(19) United States
(12) Patent Application Publication
(10) Pub. No.: US 2024/0332291 A1
(43) Pub. Date: Oct. 3, 2024

(54) SEMICONDUCTOR DEVICE AND METHOD OF MANUFACTURING SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Shoma TAKAHARA, Nonoichi Ishikawa (JP); Toru SHONO, Himeji Hyogo (JP); Koji ONISHI, Ibo Hyogo (JP); Yutaka UENO, Himeji Hyogo (JP); Takashi ISHIKAWA, Tatsuno Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/596,664

(22) Filed: Mar. 6, 2024

(30) Foreign Application Priority Data
Mar. 27, 2023 (JP) 2023-049865

(51) Int. Cl. H01L 27/088; H01L 21/8234

(52) U.S. Cl. CPC H01L 27/088; H01L 21/823425

(57) ABSTRACT

According to an embodiment, a semiconductor device includes a conductive layer, a semiconductor portion, a first source electrode, a second source electrode, a first control electrode, and a first control electrode. The semiconductor portion is provided on the conductive layer. The semiconductor portion has a first element region and a second element region. A first end portion of the conductive layer is located inside a second end portion of the semiconductor portion in a plan view. An outer periphery formed by the first end portion surrounds both at least a part of a third end portion of the first element region and at least a part of a fourth end portion of the second element region.

### CROSS-REFERENCE TO RELATED APPLICATIONS

This application is based upon and claims the benefit of priority from Japanese Patent Application No. 2023-049865, filed on Mar. 27, 2023; the entire contents of which are incorporated herein by reference.

### FIELD

Embodiments relate to a semiconductor device and a method of manufacturing the same.

### BACKGROUND

In a semiconductor device such as a vertical metal oxide semiconductor field effect transistor (MOSFET), in order to reduce an on-resistance, a study has been conducted to increase a thickness of a metal layer serving as a current path or to reduce a thickness of a semiconductor substrate.

### DESCRIPTION OF THE DRAWINGS

FIG. 1 is a schematic top view illustrating a semiconductor device according to a first embodiment;

FIG. 2 is a schematic bottom view illustrating the semiconductor device according to the first embodiment;

FIG. 3 is a schematic cross-sectional view taken along a line A-A in FIG. 1;

FIG. 4 is a schematic cross-sectional view taken along a line B1-B1 in FIG. 1;

FIG. 5 is a schematic cross-sectional view taken along a line B2-B2 in FIG. 1;

FIG. 6 is a schematic cross-sectional view taken along a line C-C in FIG. 1;

FIG. 7 is a schematic cross-sectional view taken along a line D-D in FIG. 1;

FIG. 8 is a schematic bottom view illustrating a semiconductor device according to a variation of the first embodiment;

FIG. 9 is a schematic cross-sectional view taken along a line B3-B3 in FIG. 8.;

FIG. 10 is a schematic bottom view illustrating a semiconductor device according to another variation of the first embodiment;

FIG. 11 is a schematic cross-sectional view taken along a line B4-B4 in FIG. 10;

FIGS. 12 to 19 are schematic cross-sectional views illustrating a method of manufacturing a semiconductor device according to a second embodiment;

FIG. 20 is a schematic perspective cross-sectional view illustrating a part E in FIG. 17 in an enlarged manner;

FIG. 21 is a schematic perspective cross-sectional view illustrating a region corresponding to the part E in FIG. 17 in an enlarged manner in the case of a variation corresponding to FIG. 8;

FIGS. 22 to 28 are schematic cross-sectional views illustrating a method of manufacturing a semiconductor device according to a third embodiment; and

FIG. 29 is a schematic perspective cross-sectional view illustrating a part F in FIG. 26 in an enlarged manner.

### DETAILED DESCRIPTION

A semiconductor device according to an embodiment includes: a conductive layer; a semiconductor portion provided on the conductive layer; a first source electrode provided on the semiconductor portion; a second source electrode provided on the semiconductor portion and provided away from the first source electrode; a first control electrode that is provided on the semiconductor portion and that is electrically isolated from the first source electrode and the second source electrode; and a second control electrode that is provided on the semiconductor portion and that is electrically isolated from the first source electrode, the second source electrode, and the first control electrode. The semiconductor portion includes a first semiconductor region of a first conductivity type provided on the conductive layer, a second semiconductor region of a second conductivity type provided on the first semiconductor region, a third semiconductor region of the second conductivity type provided on the first semiconductor region and provided away from the second semiconductor region, a fourth semiconductor region of the first conductivity type provided on the second semiconductor region, and a fifth semiconductor region of the first conductivity type provided on the third semiconductor region. The first source electrode is electrically connected to the second semiconductor region and the fourth semiconductor region. The second source electrode is electrically connected to the third semiconductor region and the fifth semiconductor region. The first control electrode faces the first semiconductor region, the second semiconductor region, and the fourth semiconductor region via a first insulating film. The second control electrode faces the first semiconductor region, the third semiconductor region, and the fifth semiconductor region via a second insulating film. In a plan view, a first end portion of the conductive layer is located inside a second end portion of the semiconductor portion, and an outer periphery formed by the first end portion surrounds both at least a part of a third end portion of a first element region including the second semiconductor region and at least a part of a fourth end portion of a second element region including the third semiconductor region.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In embodiments to be described below, the embodiments may be implemented by inverting a p-type and an n-type of a semiconductor region.

### First Embodiment

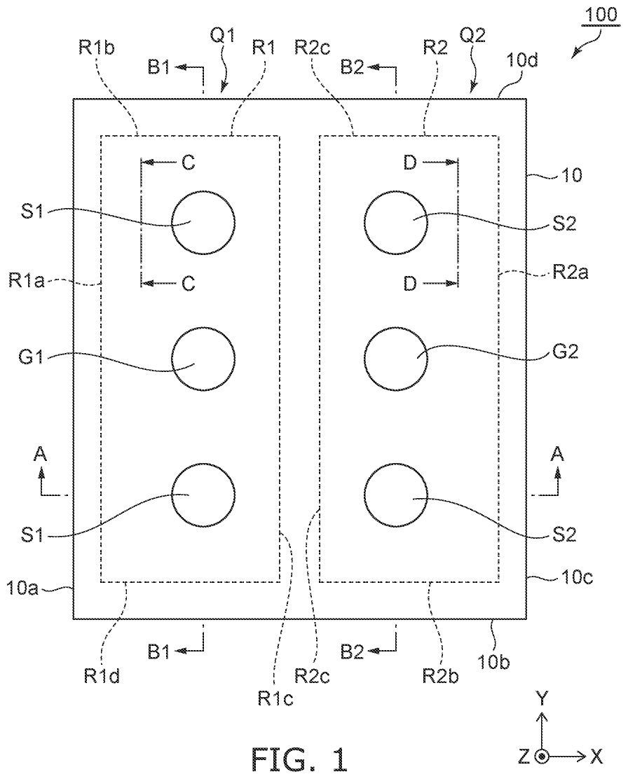

FIG. 1 is a schematic top view illustrating a semiconductor device according to a first embodiment.

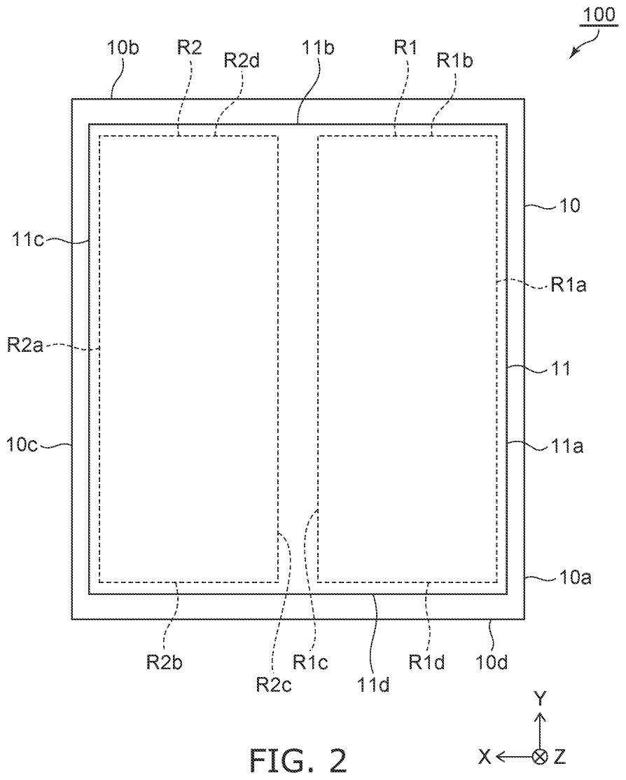

FIG. 2 is a schematic bottom view illustrating the semiconductor device according to the first embodiment.

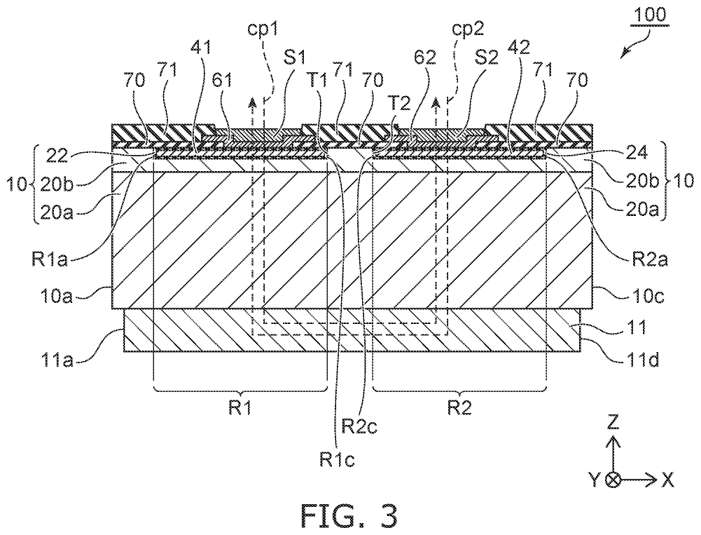

FIG. 3 is a schematic cross-sectional view taken along a line A-A in FIG. 1.

As shown in FIGS. 1 to 3, a semiconductor device 100 according to the embodiment includes a semiconductor portion 10, a lower electrode (conductive layer) 11, a first source electrode 61, a second source electrode 62, a first gate electrode (first control electrode) 41, and a second gate electrode (second control electrode) 42. The first source electrode 61 is electrically connected to a first source electrode pad S1. The second source electrode 62 is electrically connected to a second source electrode pad S2. The first gate electrode 41 is electrically connected to a first gate electrode pad G1. The second gate electrode 42 is connected to a second gate electrode pad G2.

The semiconductor portion 10 is provided on the lower electrode 11. The first source electrode 61, the second source electrode 62, the first gate electrode 41, and the second gate electrode 42 are provided on the semiconductor portion 10.

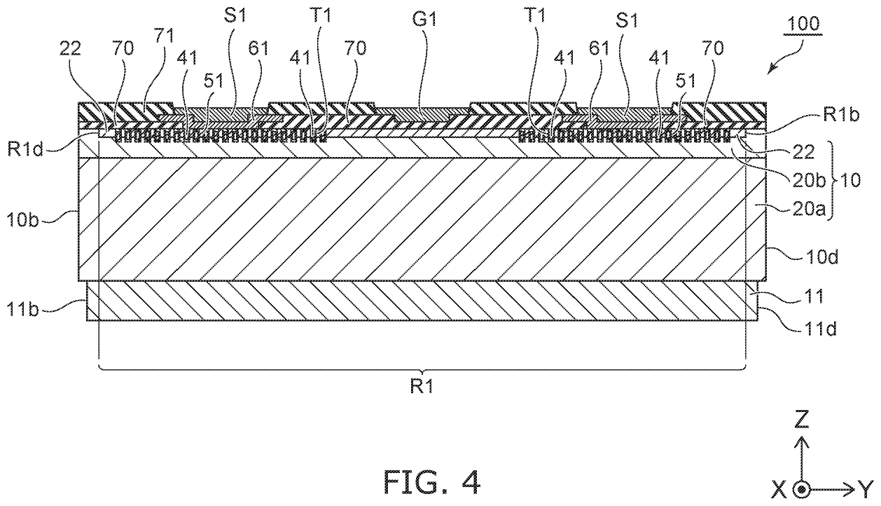

In the following description, a Z axis is a coordinate axis having a direction from the lower electrode 11 toward the semiconductor portion 10, and a direction in which the Z axis faces may be referred to as a Z direction. An X axis and a Y axis are coordinate axes orthogonal to the Z axis. A direction in which the X axis faces may be referred to as an X-direction. A direction in which the Y axis faces may be referred to as a Y-direction. For example, a plane including the X axis and the Y axis is parallel to an upper surface or a lower surface of a semiconductor substrate 20a which will be described with reference to FIGS. 3 and 4. These directions are based on a relative positional relationship between the lower electrode 11 and the semiconductor portion 10, and do not limit actual directions. A positive direction of the Z axis may be referred to as “up” and “upper”, and a negative direction of the Z axis may be referred to as “down” and “lower”. These directions are not related to a direction of gravity. The Z-direction is, for example, a direction perpendicular to an upper surface of a semiconductor substrate. A view from the positive direction to the negative direction of the Z axis may be referred to as a top view, and a view from the negative direction to the positive direction of the Z axis may be referred to as a bottom view. A plan view may be used without distinguishing a top view and a bottom view.

The semiconductor device 100 according to the embodiment includes a first element region R1 and a second element region R2. The first element region R1 and the second element region R2 are arranged apart from each other in the X-direction. A first transistor Q1 is provided in the first element region R1, and a second transistor Q2 is provided in the second element region R2. The first transistor Q1 and the second transistor Q2 are, for example, MOSFETs.

The first source electrode pad S1 and the first gate electrode pad G1 are provided on a surface side of the first element region R1. In the example, one first gate electrode pad G1 is disposed between two first source electrode pads S1 arranged together in the Y-direction. The first source electrode pad S1 is electrically connected to the first source electrode 61 on the first source electrode 61. The first gate electrode pad G1 is electrically isolated from the first source electrode pad S1 and the first source electrode 61.

Similarly, the second source electrode pad S2 and the second gate electrode pad G2 are provided on a surface side of the second element region R2. In the example, one second gate electrode pad G2 is disposed between two second source electrode pads S2 arranged together in the Y-direction. The second source electrode pad S2 is electrically connected to the second source electrode 62 on the second source electrode 62. The second gate electrode pad G2 is electrically isolated from the second source electrode pad S2 and the second source electrode 62.

The first source electrode pad S1 and the second source electrode pad S2 are arranged together in the X-direction. The first gate electrode pad G1 and the second gate electrode pad G2 are arranged together in the X-direction. An arrangement and a shape of each electrode pad shown in FIG. 1 are examples, and the embodiment is not limited to the illustrated arrangement and shape.

When the semiconductor device 100 is viewed from a lower surface, as shown in FIG. 2, an outer periphery of the first element region R1 and an outer periphery of the second element region R2 are located inside an outer periphery of the lower electrode 11. The outer periphery of the lower electrode 11 is located inside an outer periphery of the semiconductor portion 10.

The semiconductor portion 10 and the lower electrode 11 are rectangular in a plan view. The semiconductor portion 10 includes end portions 10a to 10d. The end portion 10a is located at a position facing the end portion 10c. The end portion 10b is disposed at a position facing the end portion 10d. The end portions 10b and 10d are adjacent to the end portions 10a and 10c. The lower electrode 11 includes end portions 11a to 11d. The end portion 11a is located at a position facing the end portion 11c. The end portion 11b is located at a position facing the end portion 11d. The end portions 11b and 11d are adjacent to the end portions 11a and 11c. The semiconductor portion 10 has a rectangular shape with the end portions 10a to 10d serving as an outer periphery, and the lower electrode 11 has a rectangular shape with the end portions 11a to 11d serving as an outer periphery.

The first element region R1 has, for example, a rectangular shape in a plan view, and includes four end portions R1a to R1d. The end portion R1a is disposed at a position facing the end portion R1c. The end portion R1b is disposed at a position facing the end portion R1d. The end portions R1b and R1d are adjacent to the end portions R1a and R1c. The second element region R2 has, for example, a rectangular shape in a plan view, and includes four end portions R2a to R2d. The end portion R2a is disposed at a position facing the end portion R2c. The end portion R2b is disposed at a position facing the end portion R2d. The end portions R2b and R2d are adjacent to the end portions R2a and R2c.

The first element region R1 and the second element region R2 are arranged apart from each other in the X-direction such that the end portions R1c and R2c face each other.

Shapes of an end portion of the first element region R1 and an end portion of the second element region R2 in a plan view are not limited thereto, and are freely set as appropriate. An end portion of the first element region R1 is, for example, an outermost interface in a plan view among interfaces between a first base region 22 and a drift layer 20b described with reference to FIGS. 3 and 4. An end portion of the second element region R2 is, for example, an outermost interface in a plan view among interfaces between a second base region 24 and the drift layer 20b.

In the semiconductor device 100 according to the embodiment, the end portions 11a to 11d of the lower electrode 11 may be located inside the end portions 10a to 10d of the semiconductor portion 10. It is favorable that a periphery formed by the end portions 11a to 11d of the lower electrode 11 is located outside the end portions R1a to R1d of the first element region R1 and is located outside the end portions R2a to R2d of the second element region R2.

The lower electrode 11 is formed of a material having high conductivity. The lower electrode 11 contains a metal such as aluminum, copper, silver, titanium, or tungsten. The conductivity of the lower electrode 11 is higher than the conductivity of the semiconductor portion 10. A thickness of the lower electrode 11 is, for example, smaller than a thickness of the semiconductor portion 10.

FIG. 4 is a schematic cross-sectional view taken along a line B1-B1 in FIG. 1.

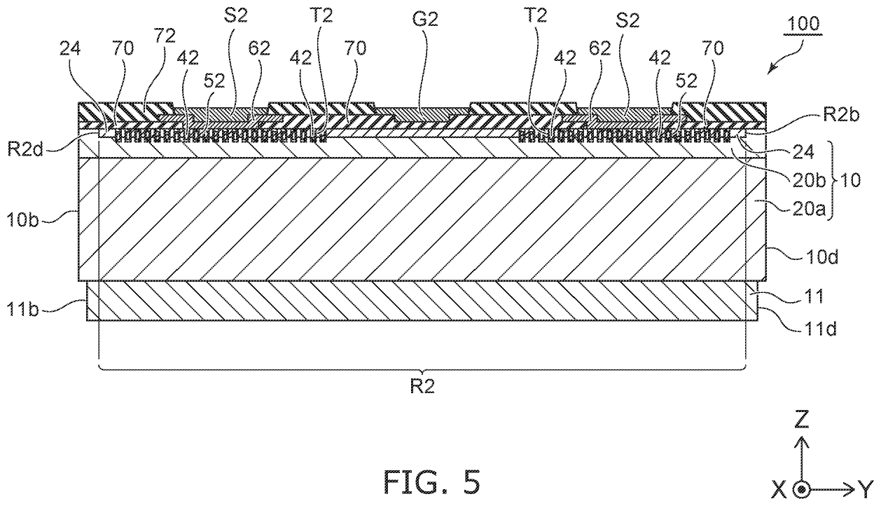

FIG. 5 is a schematic cross-sectional view taken along a line B2-B2 in FIG. 1.

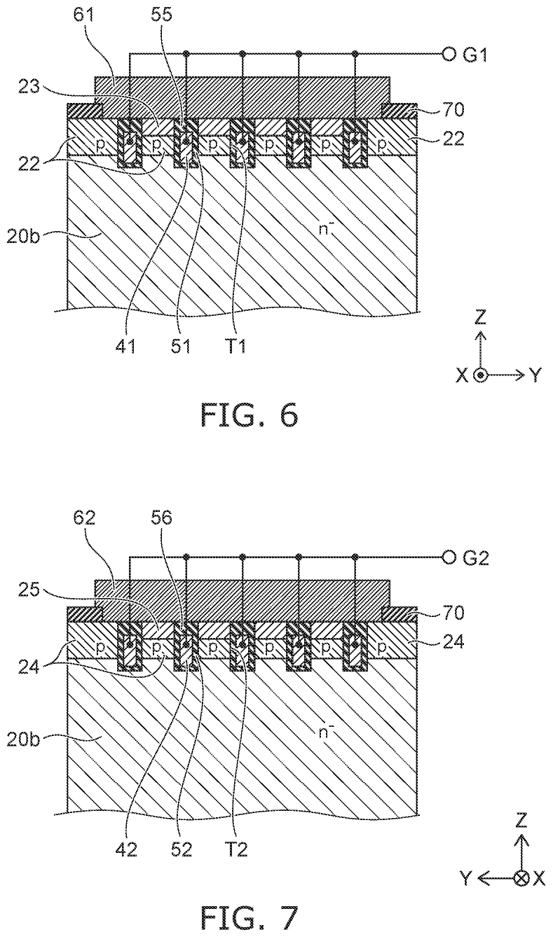

FIG. 6 is a schematic cross-sectional view taken along a line C-C in FIG. 1.

FIG. 7 is a schematic cross-sectional view taken along a line D-D in FIG. 1.

FIGS. 6 and 7 are shown in a simplified manner in order to more clearly show a configuration of a corresponding portion. Specifically, the number of the multiple first gate electrodes 41 and the number of gate insulating films 51 corresponding to the first gate electrodes 41 are smaller than those in examples in FIGS. 4 and 5. Similarly, the number of the multiple second gate electrodes 42 and the number of gate insulating films 52 corresponding to the second gate electrodes 42 are smaller than those in the examples in FIGS. 4 and 5. In FIGS. 6 and 7, a wiring structure for connecting the multiple first gate electrodes 41 to one another and electrically connecting the first gate electrodes 41 with the first gate electrode pad G1 is also simplified. Similarly, a wiring structure for connecting the multiple second gate electrodes 42 to one another and electrically connecting the second gate electrodes 42 with the second gate electrode pad G2 is also simplified.

A detailed configuration of the semiconductor device 100 according to the embodiment will be described with reference to FIGS. 3 to 7.

As shown in FIGS. 3 to 5, the semiconductor portion 10 includes the semiconductor substrate 20a and the drift layer (first semiconductor region) 20b, the first base region (second semiconductor region) 22, the second base region (third semiconductor region) 24, a first source region (fourth semiconductor region) 23, and a second source region (fifth semiconductor region) 25. The semiconductor substrate 20a is provided on the lower electrode 11. The drift layer 20b is provided on the semiconductor substrate 20a. The semiconductor substrate 20a and the drift layer 20b are provided over the entire semiconductor portion 10. That is, end portions of the semiconductor substrate 20a and the drift layer 20b coincide with the end portions 10a to 10d of the semiconductor portion 10 shown in FIGS. 1 and 2. In other words, in a plan view, outer peripheral shapes of the semiconductor substrate 20a and the drift layer 20b coincide with an outer peripheral shape of the semiconductor portion 10.

The first base region 22 and the second base region 24 are provided in the drift layer 20b and are disposed apart from each other in the X-direction. As shown in FIGS. 6 and 7, the first source region 23 is selectively provided in the first base region 22, and the second source region 25 is selectively provided in the second base region 24.

The semiconductor substrate 20a, the drift layer 20b, the first source region 23, and the second source region 25 are of a first conductivity type. The first base region 22 and the second base region 24 are of a second conductivity type. The first conductivity type is an n-type and the second conductivity type is a p-type in the semiconductor device 100 described below. The embodiment is not limited thereto, and the first conductivity type may be the p-type and the second conductivity type may be the n-type.

The first base region 22 is provided in the first element region R1. The second base region 24 is provided in the second element region R2. For example, in a plan view, an outer periphery of the first base region 22 coincides with an outer periphery of the first element region R1, and an outer periphery of the second base region 24 coincides with an outer periphery of the second element region R2. In other words, end portions of the first base region 22 coincide with end portions of the first element region R1, and end portions of the second base region 24 coincide with end portions of the second element region R2.

As shown in FIGS. 6 and 7, the multiple first gate electrodes 41 are provided in the first base region 22 via the first gate insulating films 51. The multiple first gate electrodes 41 extend in the Z-direction in a trench shape into the drift layer 20b. The multiple second gate electrodes 42 are provided in the second base region 24 via the second gate insulating films 52. The multiple second gate electrodes 42 extend in the Z-direction in a trench shape into the drift layer 20b.

In a trench T1 including the first gate electrode 41 and the first gate insulating film 51, an insulating portion 55 is provided between the first gate electrode 41 and the first source electrode 61. In a trench T2 including the second gate electrode 42 and the second gate insulating film 52, an insulating portion 56 is provided between the second gate electrode 42 and the second source electrode 62.

The multiple first gate electrodes 41 are provided together at substantially equal intervals in the Y-direction in the first base region 22. That is, the multiple first gate electrodes 41 are provided together in the Y-direction in the first element region R1. The multiple second gate electrodes 42 are provided together at substantially equal intervals in the Y-direction in the second base region 24. That is, the multiple gate electrodes 42 are provided together at substantially equal intervals in the Y-direction in the second element region R2.

As shown in FIG. 3, the multiple first gate electrodes 41 extend in a stripe shape in the X-direction in the first element region R1. The multiple second gate electrodes 42 extend in a stripe shape in the X-direction in the second element region R2.

Although not shown, the first gate electrode 41 is electrically connected to the gate electrode pad G1 shown in FIG. 1 via a conductive portion such as a gate contact and a gate wire. The second gate electrode 42 is also electrically connected to the gate electrode pad G1 shown in FIG. 1 via a conductive portion such as a gate contact and a gate wire (not shown).

The first source electrode 61 is provided on multiple first source regions 23 and is electrically connected to the multiple first source regions 23. That is, the first source electrode pad S1 is electrically connected to the first source regions 23 via the first source electrode 61. The second source electrode 62 is provided on multiple second source regions 25 and is electrically connected to the multiple second source regions 25. That is, the second source electrode pad S2 is electrically connected to the second source regions 25 via the second source electrode 62.

An insulating layer 70 is provided between the first source electrode 61 and the second source electrode 62. The first gate electrode pad G1 is provided on the insulating layer 70. Although not shown, the second gate electrode pad G2 is also provided on the insulating layer 70. Therefore, the electrode pads are electrically separated from each other. A passivation layer 71 is provided on the insulating layer 70.

The semiconductor portion 10 has a configuration as described above. The semiconductor substrate 20a, the first base region 22, the second base region 24, the first source region 23, and the second source region 25 of the semiconductor portion 10 contain silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The first source electrode 61, the second source electrode 62, the first source electrode pad S1, the second source electrode pad S2, the first gate electrode pad G1, and the second gate electrode pad G2 contain a metal such as aluminum, copper, silver, titanium, or tungsten.

Although the first transistor Q1 and the second transistor Q2 have a stripe-shaped trench gate structure in the above description, the first transistor Q1 and the second transistor Q2 are not limited thereto, and may have a mesh-shaped trench gate structure. The first transistor Q1 and the second transistor Q2 are not limited to a trench gate structure, and may have any other appropriate transistor structures. For example, the first transistor Q1 and the second transistor Q2 may have a planar gate structure.

An operation and effects of the semiconductor device 100 according to the embodiment will be described.

First, an electrical operation of the semiconductor device 100 will be described.

The first transistor Q1 is a MOSFET including, as a drain electrode, the semiconductor substrate 20a provided via the drift layer 20b, and including the first source electrode 61 and the first gate electrode 41. In the first transistor Q1, a current flowing between the drift layer 20b and the first source electrode 61 can be controlled by controlling a voltage of the first gate electrode 41 relative to the first source electrode 61. The second transistor Q2 is a MOSFET including, as a drain electrode, the semiconductor substrate 20a provided via the drift layer 20b, and including the second source electrode 62 and the second gate electrode 42. In the second transistor Q2, a current flowing between the drift layer 20b and the second source electrode 62 can be controlled by controlling a voltage of the second gate electrode 42 relative to the second source electrode 62.

In the semiconductor device 100, the first transistor Q1 and the second transistor Q2 are electrically connected by the drift layer 20b. That is, the semiconductor device 100 constitutes a reverse series circuit in which the first transistor Q1 and the second transistor Q2 are connected by drain electrodes.

In the semiconductor device 100, the drift layer 20b is provided on the semiconductor substrate 20a, the lower electrode 11 is provided on the semiconductor substrate 20a and the lower electrode 11 is electrically connected to the semiconductor substrate 20a. That is, the lower electrode 11 is electrically connected to the drift layer 20b via the semiconductor substrate 20a. The conductivity of the lower electrode 11 is fairly higher than the conductivity of the semiconductor substrate 20a and the conductivity of the drift layer 20b. Therefore, most of a current flowing through the first transistor Q1 and the second transistor Q2 is shunted to the lower electrode 11.

Broken line arrows in FIG. 3 indicate current paths cp1 and cp2 shunted to the lower electrode 11. The current path cp1 is a path of a current flowing from the first source electrode pad S1 to the second source electrode pad S2. The current path cp2 is a path of a current flowing from the second source electrode pad S2 to the first source electrode pad S1. In this manner, a current flowing between the first transistor Q1 and the second transistor Q2 flows through the semiconductor portion 10 along a thickness direction of the semiconductor portion 10, and flows through the lower electrode 11 in a direction intersecting a thickness direction of the lower electrode 11.

A resistance value in a direction in which a current flows through the semiconductor portion 10 can be reduced by reducing a thickness of the semiconductor portion 10. A resistance value in a direction in which a current flows through the lower electrode 11 can be reduced by increasing a thickness of the lower electrode 11. That is, in the semiconductor device 100, a voltage drop during conduction of the semiconductor device 100 can be prevented and a heat loss can be reduced, by reducing the thickness of the semiconductor portion 10 and increasing the thickness of the lower electrode 11.

Next, a mechanical operation of the semiconductor device 100 will be described.

Here, the mechanical operation refers to an operation of applying a shear stress based on a difference between a linear expansion coefficient of the semiconductor portion 10 and a linear expansion coefficient of the lower electrode 11 when a thermal stress is applied to the semiconductor device 100.

The semiconductor portion 10 and the lower electrode 11 are formed of the materials described above. The linear expansion coefficient of the lower electrode 11 is larger than the linear expansion coefficient of the semiconductor portion 10. When a thermal stress is applied to such a semiconductor device 100, the lower electrode 11 expands more than the semiconductor portion 10. Therefore, the semiconductor device 100 is warped in a manner of protruding in a negative direction of the Z axis.

The larger a volume of a member, the larger an amount of warpage of the semiconductor device 100 based on the difference between the linear expansion coefficients. Therefore, as the thickness of the semiconductor portion 10 is reduced, an increase amount of a volume of the semiconductor portion 10 when a thermal stress is applied is reduced. On the other hand, as the thickness of the lower electrode 11 increases, the increase amount of a volume of the lower electrode 11 when a thermal stress is applied is increased. In order to reduce the amount of warpage of the semiconductor device 100, it is required to increase the thickness of the semiconductor portion 10 and reduce the thickness of the lower electrode 11.

As described above in the electrical operation, when the thickness of the semiconductor portion 10 is reduced and the thickness of the lower electrode 11 is increased, it is advantageous for the characteristics of the semiconductor device 100. On the other hand, it is favorable to increase the thickness of the semiconductor portion 10 and reduce the thickness of the lower electrode 11 from the viewpoint of reducing the amount of warpage generated in the semiconductor device 100 due to the shear stress generated based on the difference between the linear expansion coefficients.

That is, there is a tradeoff relationship between electrical characteristics and mechanical characteristics, and the thickness of the semiconductor portion 10 and the thickness of the lower electrode 11 are appropriately set for each semiconductor device according to a material of the semiconductor portion 10 and a material of the lower electrode 11.

In the semiconductor device 100 according to the embodiment, end portions of the lower electrode 11 are located inside end portions of the semiconductor device 100 in a plan view. Since the lower electrode 11 has a sufficient thickness, and a volume of the lower electrode 11 can be reduced while achieving low resistance, the volume can be prevented from increasing when a thermal stress is applied. Therefore, in the semiconductor device 100 according to the embodiment, warpage of the semiconductor device 100 due to the application of the thermal stress can be reduced.

Further, end portions of the lower electrode 11 is disposed outside a region extending over the first element region R1 and the second element region R2. In the semiconductor portion 10, since a current flows substantially along the thickness direction of the semiconductor portion 10, the current flowing through the semiconductor portion 10 can be more reliably guided to the lower electrode 11. Therefore, a resistance value between the first transistor Q1 provided in the first element region R1 and the second transistor Q2 provided in the second element region R2 can be effectively reduced.

The semiconductor device 100 having the above-described configuration is used as a bidirectional switch circuit. The bidirectional switch circuit is mounted in a battery pack of a lithium ion secondary battery for, for example, over-discharge protection and over-charge protection of the lithium ion secondary battery. A battery pack of a lithium ion secondary battery is continuously improved in energy capacity and is reduced in size and increased in capacity. In order to reduce a size of a battery pack, it is necessary to reduce a size and a thickness of a circuit board on which a bidirectional switch circuit is mounted, and higher mountability is required for circuit components. Further, it is required to prevent warpage of circuit components even in flow mounting or the like with high temperature solder, and it is required to achieve high yield. In the semiconductor device 100 according to the embodiment, since the amount of warpage of the semiconductor device 100 is reduced, it is possible to easily cope with reduction in a size and a thickness of a device such as a battery pack.

From the viewpoint of increasing a capacity of a battery pack, high performance of a bidirectional switch circuit is required. Specifically, it is required to reduce a voltage drop due to low on-resistance. Therefore, an increase in a size of the bidirectional switch circuit is unavoidable, and a bidirectional switch having performance that meets requirements of a device is required.

The amount of warpage of the semiconductor device 100 increases as a length in a longitudinal direction of the semiconductor portion 10 increases. For example, when simple approximation is used, the amount of warpage increases in proportion to square of the length in the longitudinal direction. When a size of the semiconductor device 100 is increased in response to an increase in a capacity of a battery pack, the length of the semiconductor portion 10 in the X-direction or the Y-direction increases, and an absolute amount of the warpage of the semiconductor device 100 increases.

Since the semiconductor device 100 according to the embodiment has the above-described configuration, it is possible to increase a size of a shape of the semiconductor portion 10 in a plan view while preventing an increase in the volume of the lower electrode 11.

In the above description, end portions of the lower electrode 11 can be freely set to any position as appropriate based on a current density distribution formed in the lower electrode 11 by a current flowing in a thickness direction of the semiconductor portion 10 in the first element region R1 and the second element region R2. That is, in a plan view, the lower electrode 11 is not limited to a case where an outer periphery formed by the end portions of the lower electrode 11 surrounds all end portions of the first element region R1 and all end portions of the second element region R2, and the outer periphery may surround both at least a part of the end portions of the first element region R1 and at least a part of the end portions of the second element region R2.

### (Variation 1)

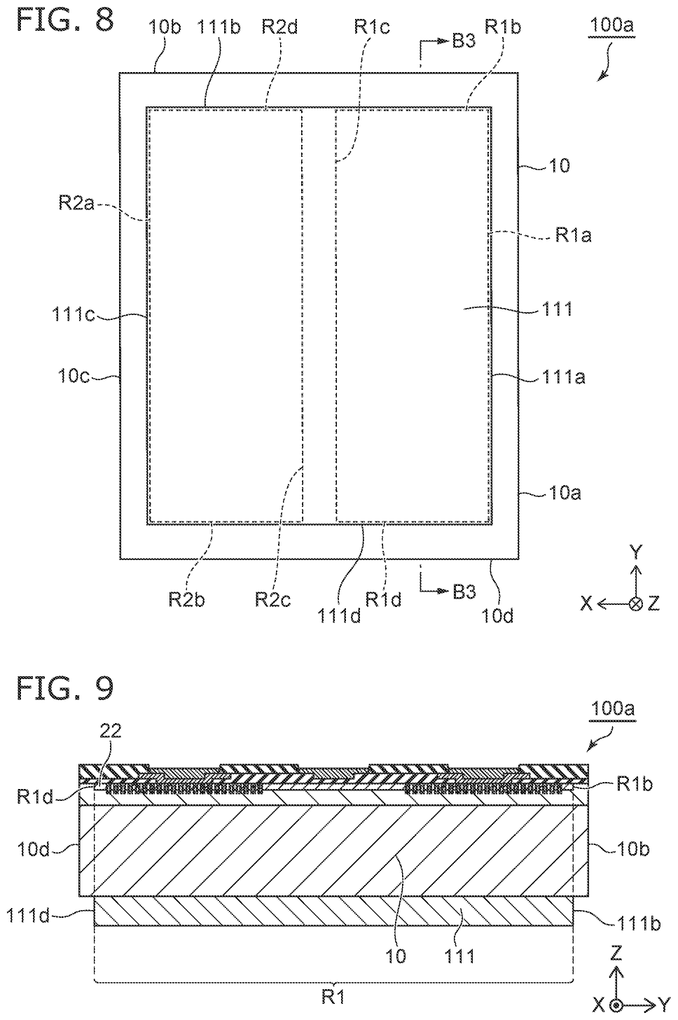

FIG. 8 is a schematic bottom view illustrating a semiconductor device according to a variation of the first embodiment.

FIG. 9 is a schematic cross-sectional view taken along a line B3-B3 in FIG. 8.

As shown in FIGS. 8 and 9, a semiconductor device 100a according to the variation includes a lower electrode 111. The lower electrode 111 is different from the lower electrode 11 of the semiconductor device 100 shown in FIGS. 1 to 5. In other respects, the semiconductor device 100a according to the variation is the same as the semiconductor device 100, the same components are denoted by the same reference signs, and detailed description thereof will be omitted.

End portions of the lower electrode 111 coincide with an envelope of end portions of the first element region R1 and end portions of the second element region R2. In FIGS. 1 and 2, the envelope of the end portions of the first element region R1 and the end portions of the second element region R2 are lines connecting the end portions R1a, R1b, R2d, R2a, R2b, and R1d. For example, as shown in FIGS. 3 to 5, end portions of the first element region R1 are end portions of the first base region 22, and end portions of the second element region R2 are end portions of the second base region 24.

In the variation, a current flowing between the first element region R1 and the lower electrode 111 and a current flowing between the second element region R2 and the lower electrode 111 can be induced to the lower electrode 111 without leakage and can be shunted. Therefore, the semiconductor device 100a can achieve a fairly low on-resistance value while preventing an increase in a volume of the lower electrode 111.

In the variation, end portions of the lower electrode 111 can be freely set to any position as appropriate based on a current density distribution formed in the lower electrode 111 by a current flowing in a thickness direction of the semiconductor portion 10 in the first element region R1 and the second element region R2.

### (Variation 2)

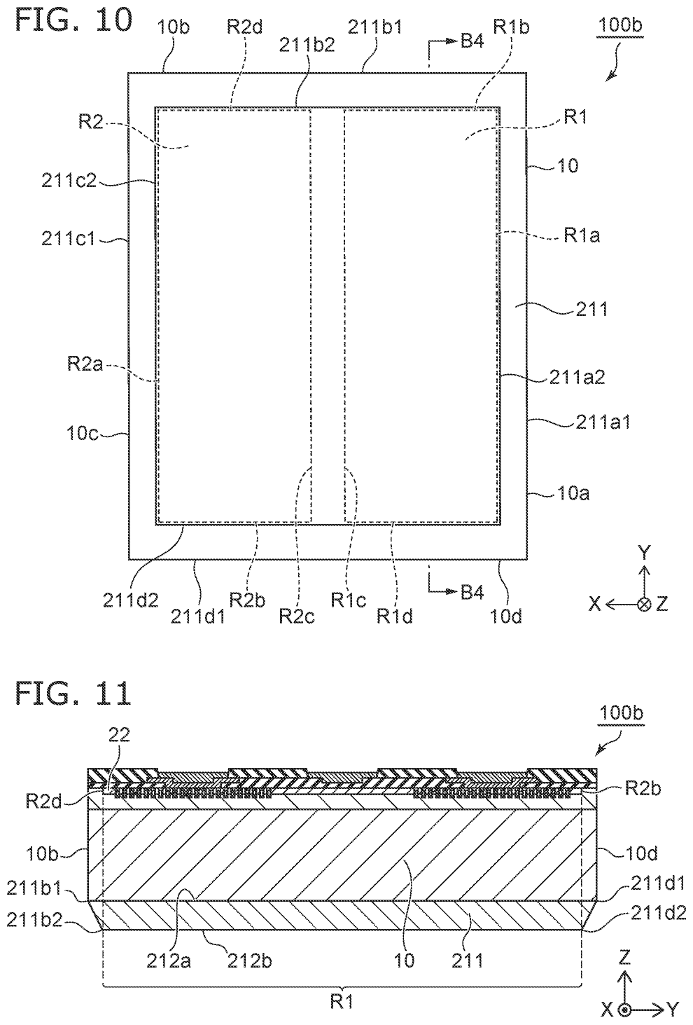

FIG. 10 is a schematic bottom view illustrating a semiconductor device according to another variation of the first embodiment.

FIG. 11 is a schematic cross-sectional view taken along a line B4-B4 in FIG. 10.

As shown in FIGS. 10 and 11, a semiconductor device 100b according to the variation includes a lower electrode 211. The lower electrode 211 is different from the lower electrode 11 of the semiconductor device 100 shown in FIGS. 1 to 4. In other respects, the semiconductor device 100b according to the variation is the same as the semiconductor device 100, the same components are denoted by the same reference signs, and detailed description thereof will be omitted.

The lower electrode 211 has a frustum shape. The frustum may have a substantially rectangular shape with rounded corners in a plan view. The frustum has an upper surface 212a and a lower surface 212b. The upper surface 212a of the frustum is a region surrounded by end portions 211a1 to 211d1 that coincide with the end portions 10a to 10d of the semiconductor portion 10. For example, the lower surface 212b of the frustum is a region surrounded by end portions 211a2 to 211d2 that coincide with an envelope of end portions of the first element region R1 and end portions of the second element region R2. That is, the lower electrode 211 has a frustum shape that gradually becomes thinner from a positive direction to a negative direction of the Z axis. A side surface of the frustum is not limited to a linear shape as in the example, and may be a convex or concave curved surface.

In the variation, the lower electrode 211 has a sufficient thickness in a region surrounded by an envelope of the end portions of the first element region R1 and the end portions of the second element region R2, and a resistance value in a direction intersecting the thickness direction of the semiconductor portion 10 is lowered. On the other hand, outside the envelope of the end portions of the first element region R1 and the end portions of the second element region R2, an inclination of a truncated quadrangular pyramid prevents an increase in a volume of the lower electrode 211, and prevents an increase in the volume of the lower electrode 211 when a thermal stress is applied.

In this manner, a current flowing between the first element region R1 and the lower electrode 211 and a current flowing between the second element region R2 and the lower electrode 211 can be guided to the lower electrode 211 without leakage and can be shunted in the variation. Therefore, it is possible to achieve a fairly low on-resistance value while preventing an increase in a volume of the lower electrode 211.

In the variation, a slope of the truncated quadrangular pyramid may not be planar, and may be a curved surface that is convex in the negative direction of the Z axis or is convex in the positive direction of the Z axis, or may have a stepped shape having multiple steps.

In the variation, end portions of the lower electrode 211 can be appropriately set to any position and can be appropriately formed in any shape based on a current density distribution formed in the lower electrode 211 by a current flowing in the thickness direction of the semiconductor portion 10 in the first element region R1 and the second element region R2.

### Second Embodiment

Hereinafter, a method of manufacturing the semiconductor device 100 described in the first embodiment will be described.

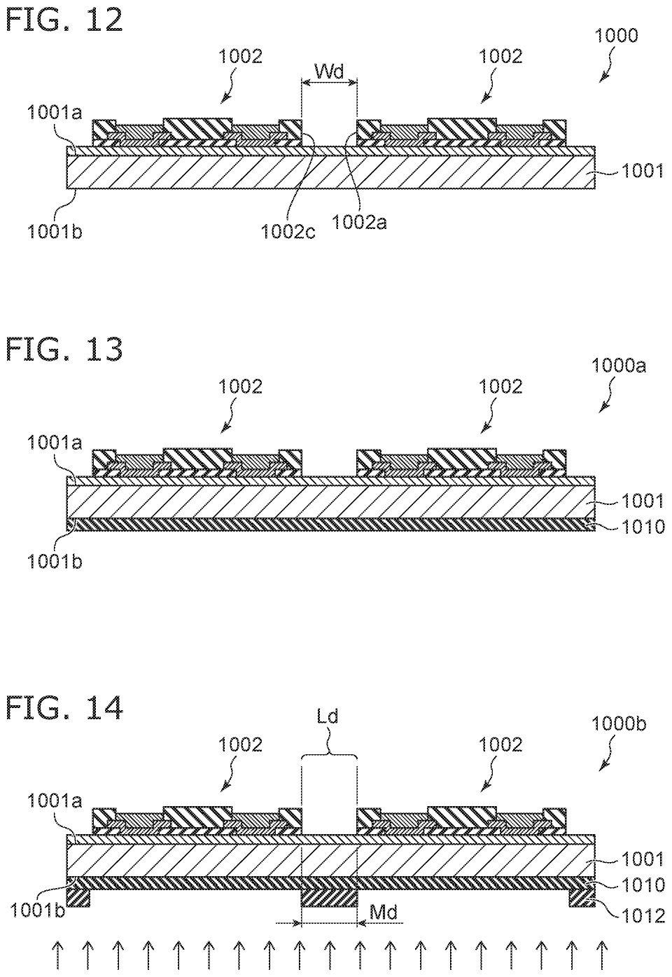

FIGS. 12 to 19 are schematic cross-sectional views illustrating a method of manufacturing a semiconductor device according to a second embodiment.

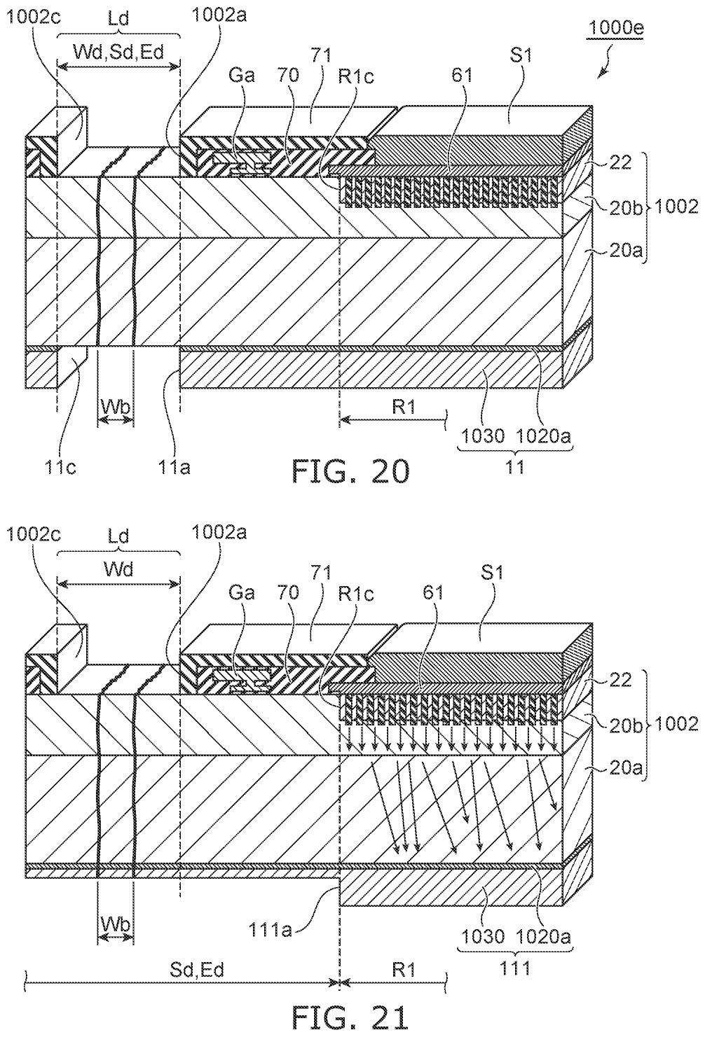

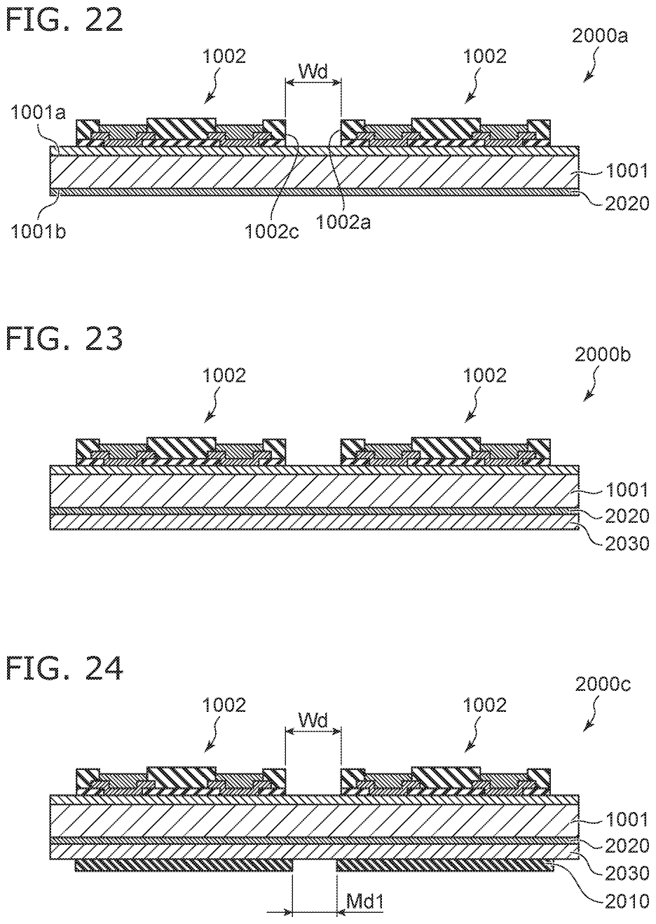

In FIGS. 12 to 19, a structure above the semiconductor substrate 20a in the semiconductor portion 10 described with reference to FIG. 1 and the like is simplified to avoid complexity in the shown case. FIGS. 22 to 28 in a third embodiment to be described later are also shown in a simplified manner. The simplified portion is a semiconductor layer 1002. The semiconductor layer 1002 includes the drift layer 20b, the first base region 22, the second base region 24, the first source region 23, the second source region 25, the first gate electrode 41, and the second gate electrode 42 of the semiconductor device 100 shown in FIGS. 3 to 5. The first source electrode 61, the second source electrode 62, the first source electrode pad S1, the second source electrode pad S2, the first gate electrode pad G1, and the second gate electrode pad G2 that are shown in FIGS. 3 to 5 are formed on the semiconductor layer 1002, and further the insulating layer 70 and the passivation layer 71 are also provided on the semiconductor layer 1002. In the semiconductor layer 1002, only a portion corresponding to the drift layer 20b is provided on the semiconductor substrate 20a at a position corresponding to a dicing line Ld.

As shown in FIG. 12, an intermediate member 1000 is prepared. The intermediate member 1000 includes a semiconductor substrate 1001 and the semiconductor layer 1002. Multiple semiconductor layers 1002 are formed on the semiconductor substrate 1001. The semiconductor substrate 1001 has a first face 1001a and a second face 1001b. The second face 1001b is a face located on a side opposite to the first face. The multiple semiconductor layers 1002 are formed on the first face 1001a of the semiconductor substrate 1001.

The multiple semiconductor layers 1002 are formed on the semiconductor substrate 1001 in a manner of being separated from one another by a dicing width Wd. The semiconductor substrate 1001 is, for example, a silicon wafer, and the multiple semiconductor layers 1002 are formed in a grid pattern on a silicon substrate that is the semiconductor substrate 1001. The dicing width Wd is provided to insert a dicing blade to be described later and divide the semiconductor substrate 1001 for each semiconductor layer 1002. The dicing width Wd is set in advance according to a width of the dicing blade and accuracy of an insertion position of the dicing blade.

In the adjacent semiconductor layers 1002, end portions 1002a and 1002c of the semiconductor layers 1002 are separated from each other by the dicing width Wd.

As shown in FIG. 13, a resist layer 1010 is formed on the second face 1001b of the semiconductor substrate 1001 of the intermediate member 1000 shown in FIG. 12, and an intermediate member 1000a is formed. The resist layer 1010 is formed over the entire second face 1001b.

As shown in FIG. 14, a mask 1012 is formed on a side where the resist layer 1010 is formed. The mask 1012 is provided at a position corresponding to the dicing line Ld. The mask 1012 has a mask width Md equal to the dicing width Wd which is a width of the dicing line.

An intermediate member 1000b on which the mask 1012 is formed is exposed from a side where the resist layer 1010 is formed, and the resist layer 1010 is patterned.

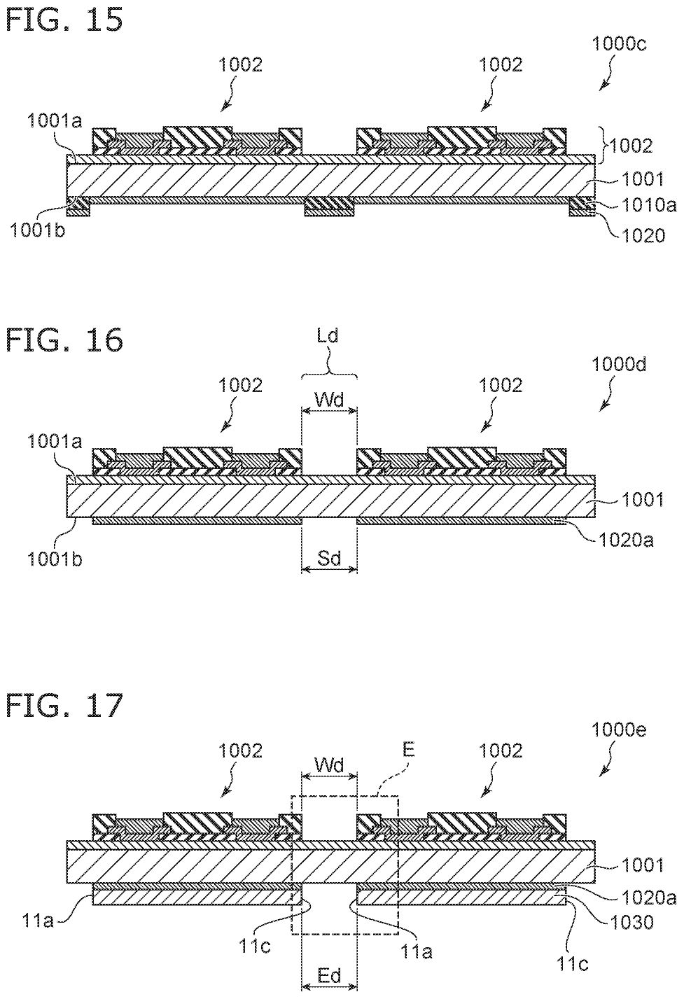

As shown in FIG. 15, the mask 1012 shown in FIG. 14 is removed after the exposure, and a seed metal layer 1020 is formed on the second face 1001b and a resist 1010a remained on the mask 1012, and an intermediate member 1000c is formed. The seed metal layer 1020 is formed by, for example, vacuum deposition or sputtering.

As shown in FIG. 16, the resist 1010a shown in FIG. 15 is removed, and an intermediate member 1000d is formed. By removing the resist 1010a, a seed metal 1020a is formed at a position other than a position corresponding to the dicing line Ld. Therefore, a distance Sd between the two adjacent seed metals 1020a is substantially equal to the dicing width Wd.

As shown in FIG. 17, a lower electrode 1030 is formed on the seed metal 1020a, and an intermediate member 1000e is formed. The lower electrode 1030 can be formed by, for example, electrolytic plating. A sufficient thickness can be attained by forming the lower electrode 1030 by electrolytic plating.

Since the lower electrodes 1030 are formed at positions of the seed metals 1020a by forming the lower electrodes 1030 using electrolytic plating, a distance Ed between the two adjacent lower electrodes 1030 is substantially equal to the distance Sd between the adjacent seed metals 1020a. That is, the end portions 11a and 11c of the adjacent lower electrodes 1030 are separated by the distance Sd.

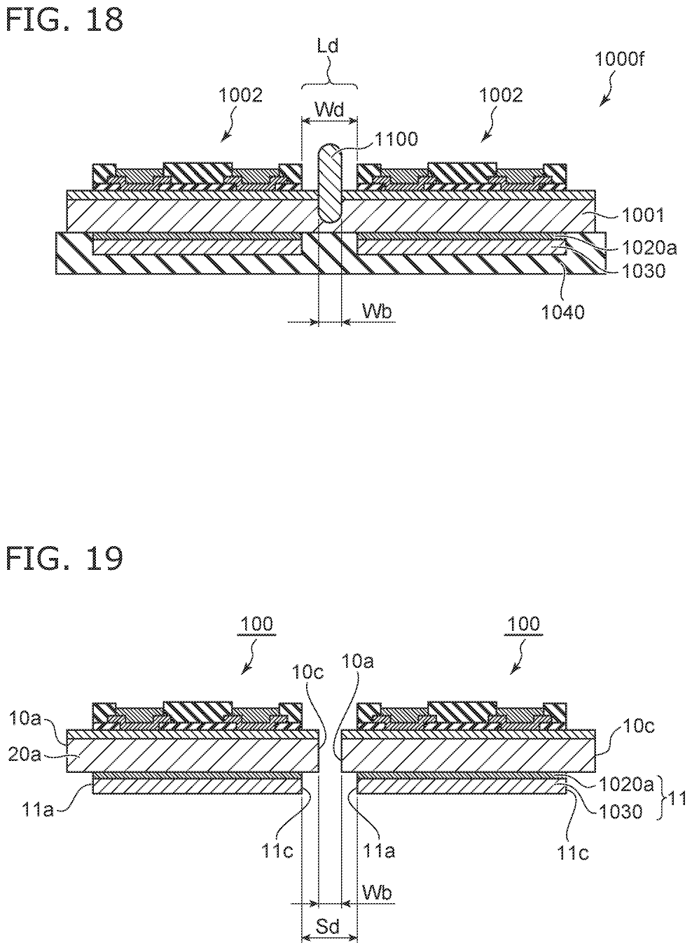

As shown in FIG. 18, a dicing sheet 1040 is attached to the intermediate member 1000e shown in FIG. 17, and an intermediate member 1000f is formed. The dicing sheet 1040 is attached to the second face 1001b side of the semiconductor substrate 1001. The dicing sheet 1040 is provided to prevent the divided semiconductor layers 1002 and the semiconductor substrate 1001 from scattering after the intermediate member 1000f is divided for each semiconductor layer 1002.

A dicing blade 1100 is positioned according to the dicing line Ld. In the dicing line Ld, an insertion position of the dicing blade 1100 is, for example, ½ of the dicing width Wd. The dicing width Wd is set based on a width Wb of the dicing blade 1100 when the insertion position of the dicing blade 1100 is a position of ½ of the dicing width Wd. More specifically, ½Wd>½Wb+position setting accuracy of the dicing blade. With such setting, it is possible to prevent the dicing blade 1100 from cutting the semiconductor layer 1002.

As shown in FIG. 19, the intermediate member 1000f shown in FIG. 18 is divided by the dicing blade 1100, and multiple semiconductor devices 100 are formed. In the multiple semiconductor devices 100, a face cut by the dicing blade 1100 forms an end portion. In the example in FIG. 19, the semiconductor device 100 includes the one end portion 10a and the other end portion 10c. In two semiconductor devices 100 each having the two semiconductor layers 1002 disposed adjacent to each other, the end portion 10a of the one semiconductor device 100 is located at a position facing the end portion 10c of the other semiconductor device 100, and is an end portion cut by the one dicing blade 1100. Immediately after the dividing, the end portions 10a and 10c are separated by about the width Wb of the dicing blade.

The seed metals 1020a and the lower electrodes 1030 of the semiconductor device 100 after the dividing constitute the lower electrode 11. As shown in FIGS. 16 to 18, the two adjacent seed metals 1020a are separated by the distance Sd, and the two adjacent lower electrodes 1030 are separated by the distance Ed. The distances Sd and Ed are set to be equal to the dicing width Wd. On the other hand, the dicing width Wd is set to be fairly wide based on the width Wb of the dicing blade 1100 and setting position accuracy of the dicing blade. Therefore, the distances Sd and Ed are fairly larger than the width Wb of the dicing blade. That is, in the semiconductor device 100, end portions of the lower electrode 11 are disposed inside end portions of the semiconductor portion 10. Immediately after the dividing, the end portions 11a and 11c are separated by the distance Ed=Sd. Since the distance Ed=Sd is larger than the width Wb of the dicing blade, end portions of the lower electrode 11 is located inside end portions of the semiconductor substrate.

FIG. 20 is a schematic perspective cross-sectional view illustrating a part E in FIG. 17 in an enlarged manner.

As shown in FIG. 20, in the intermediate member 1000e, the semiconductor layer 1002 includes the semiconductor substrate 20a, the drift layer 20b, and the first base region 22, and an end portion of the first base region 22 is the end portion R1a of the first element region R1. Since detailed description has been made with reference to FIGS. 3 to 6 in which the first source electrode 61 is formed in the first base region 22 via the first source region, detailed description is omitted here.

In the example, a gate wire Ga connected to the first gate electrode 41 shown in FIG. 4 is provided outside the end portion R1a, and the gate wire Ga is covered with the insulating layer 70 and the passivation layer 71. Therefore, the end portion 1002a of the semiconductor layer 1002 is located outside the end portion R1a of the first element region R1. In another example, another wire layer or the like may be formed in a region between an end portion of the semiconductor layer 1002 and an end portion of the first element region R1, and the dicing line Ld is required to have a sufficient distance between the adjacent semiconductor layers 1002.

FIG. 21 is a schematic perspective cross-sectional view illustrating a region corresponding to the part E in FIG. 17 in an enlarged manner in the case of the variation corresponding to FIG. 8.

In FIG. 21, arrows indicate that a current in the first element region R1 flows in a thickness direction of the drift layer 20b and the semiconductor substrate 20a. As shown in FIG. 21, a region that is not a path of a current flowing through the first element region R1 and the second element region R2 may be formed outside an end portion of the first element region R1 and an end portion of the second element region R2. That is, FIG. 21 shows that a current flowing in the thickness direction of the drift layer 20b and the semiconductor substrate 20a is less likely to flow to the outside from the end portion R1a of the first element region R1. An end portion 111a of the lower electrode 111 is determined based on a boundary at which a current density is fairly high when the current flowing in the thickness direction of the drift layer 20b and the semiconductor substrate 20a flows to the lower electrode 111. In the example in FIG. 21, the boundary is the end portion R1a of the first element region R1.

In the example in FIG. 21, a position of the end portion 111a of the lower electrode 111 can be set by adjusting the width Md of the mask 1012 described with reference to FIG. 14. Specifically, the position of the end portion of the lower electrode 111 can be made sufficiently inside a position of an end portion of the semiconductor portion 10 by making the mask width Md sufficiently larger than the dicing width Wd. By using a position of an end portion of the first element region R1 and a position of an end portion of the second element region R2, the mask width Md can be set such that the position of the end portion of the lower electrode 111 coincides with the position of the end portion of the first element region R1 and the position of the end portion of the second element region R2.

The effect of the method of manufacturing the semiconductor device according to the embodiment will be described.

In the method of manufacturing the semiconductor device according to the embodiment, the end portion of the lower electrode 11 can be more reliably disposed inside the end portion of the semiconductor portion 10 by making the mask width Md of the seed metal for forming the lower electrode 11 equal to or larger than the dicing width Wd. The semiconductor device 100 is formed in this manner, so that the semiconductor device 100 that is less warped when a thermal stress is applied can be formed.

In the method of manufacturing the semiconductor device according to the embodiment, the end portion of the lower electrode 11 is reliably disposed inside the end portion of the semiconductor portion 10, so that it is possible to prevent the dicing blade 1100 from cutting the seed metal 1020a and the lower electrode 1030. A metal portion including the seed metal 1020a and the lower electrode 1030 is prevented from being cut by the dicing blade 1100, so that it is possible to prevent burrs from occurring in the metal portion due to the cutting of the metal portion. The metal portion is prevented from being cut, so that cracking of a blade of the dicing blade 1100 can be prevented, chipping caused by the cracking can be prevented, the semiconductor device 100 can be manufactured more smoothly, and quality of the semiconductor device 100 can be improved.

### Third Embodiment

Hereinafter, a method of manufacturing a semiconductor device 100b described with reference to FIGS. 10 and 11 will be described.

FIGS. 22 to 28 are schematic cross-sectional views illustrating the method of manufacturing the semiconductor device according to the third embodiment.

As shown in FIG. 22, the intermediate member 1000 shown in FIG. 12 is prepared, a seed metal layer 2020 is formed on the second face 1001b of the semiconductor substrate 1001 of the intermediate member 1000, and an intermediate member 2000a is formed. The seed metal layer 2020 is formed over the entire second face 1001b. In the seed metal layer 2020, for example, is formed by using vacuum deposition or sputtering.

As shown in FIG. 23, a lower electrode layer 2030 is formed on the seed metal layer 2020 of the intermediate member 2000a shown in FIG. 22, and an intermediate member 2000b is formed. The lower electrode layer 2030 is formed using, for example, electrolytic plating, and the lower electrode layer 2030 is formed on an entire face of the seed metal layer 2020 by electrolytic plating. The lower electrode layer 2030 having a sufficient thickness can be formed by electrolytic plating.

As shown in FIG. 24, a resist mask 2010 is formed on the lower electrode layer 2030, and an intermediate member 2000c is formed. The resist mask 2010 is provided at a position corresponding to the semiconductor layer 1002, and a distance Md1 between the adjacent resist masks 2010 is set according to the dicing width Wd. For example, the distance Md1 of the resist masks 2010 is set to be equal to or larger than the dicing width Wd.

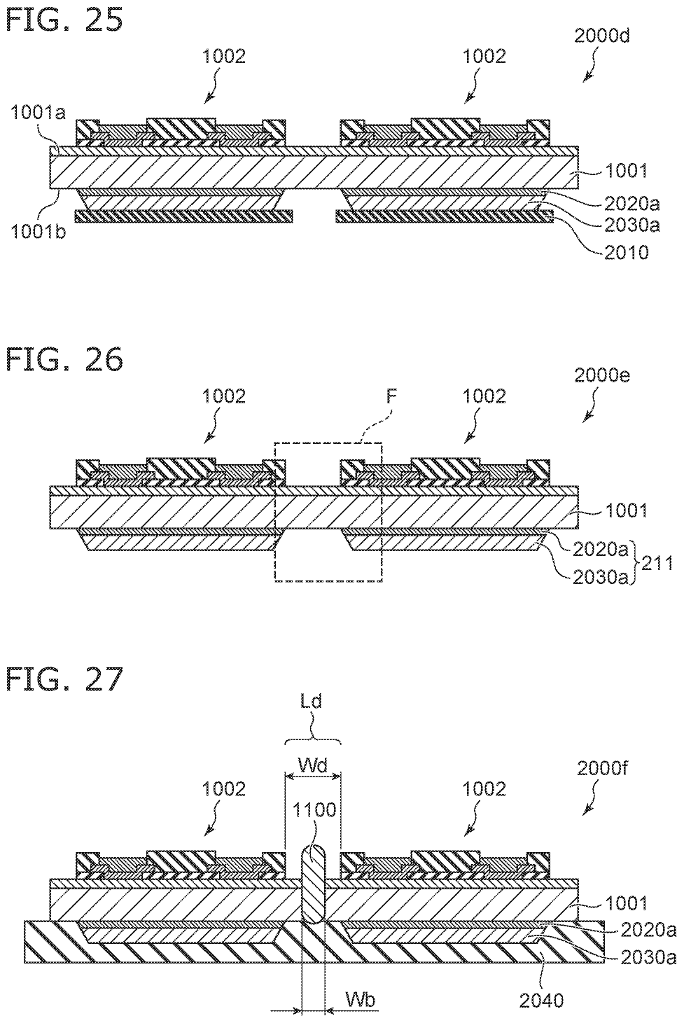

As shown in FIG. 25, the intermediate member 2000c shown in FIG. 24 is immersed in an etching solvent, the seed metal layer 2020 and the lower electrode layer 2030 are divided, and an intermediate member 2000d including the lower electrode 2030a formed on a seed metal 2020a is formed. In the formation of the intermediate member 2000d, since the seed metal layer 2020 and the lower electrode layer 2030 are divided by wet etching, etching of the seed metal layer 2020 and the lower electrode layer 2030 proceeds in the same direction, and the seed metal 2020a and the lower electrode 2030a are formed into a frustum shape that becomes thinner in a direction from the first face 1001a toward the second face 1001b of the semiconductor substrate 1001.

As shown in FIG. 26, the resist mask 2010 shown in FIG. 25 is removed, and an intermediate member 2000e is formed.

As shown in FIG. 27, a dicing sheet 2040 is attached to the intermediate member 2000e shown in FIG. 26, and an intermediate member 2000f is formed. After the intermediate member 2000f is divided for each semiconductor layer 1002, the dicing sheet 2040 is provided to prevent the divided semiconductor layers 1002 and the semiconductor substrate 1001 from scattering.

The dicing blade 1100 is positioned according to the dicing line Ld. In the dicing line Ld, an insertion position of the dicing blade 1100 is, for example, ½ of the dicing width Wd. The dicing width Wd is set based on a width Wb of the dicing blade 1100 when the insertion position of the dicing blade 1100 is a position of ½ of the dicing width Wd. More specifically, ½Wd>½Wb+position setting accuracy of the dicing blade. With such setting, it is possible to prevent the dicing blade 1100 from cutting the semiconductor layer 1002.

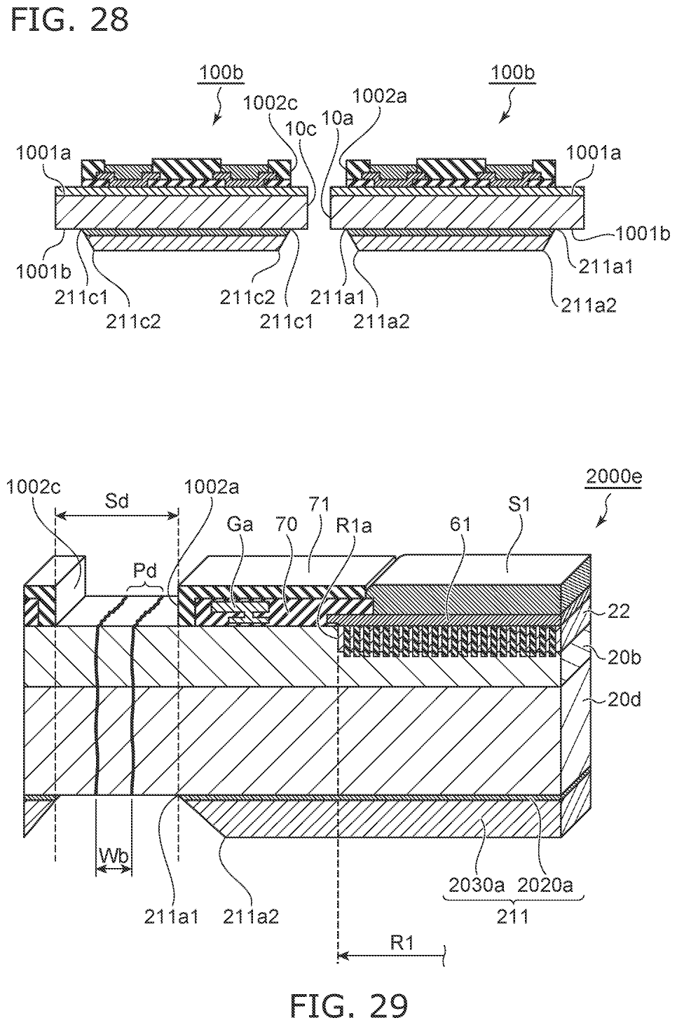

As shown in FIG. 28, the intermediate member 2000f shown in FIG. 27 is divided by the dicing blade 1100, and multiple semiconductor devices 100b are formed. In the multiple semiconductor devices 100b, a surface cut by the dicing blade 1100 forms an end portion. In the example in FIG. 28, the semiconductor device 100b includes the one end portion 10a and the other end portion 10c. In two semiconductor devices 100b each having the two semiconductor layers 1002 disposed adjacent to each other, the end portion 10a of the one semiconductor device 100b is located at a position facing the end portion 10c of the other semiconductor device 100b, and is an end portion cut by the one dicing blade 1100.

In the two semiconductor devices 100b each having the two semiconductor layers disposed adjacent to each other, the two semiconductor devices 100b are separated from each other by the distance Md1 of the resist mask 2010 set based on the dicing width Wd, and the distance Md1 can be made equal to or larger than the dicing width Wd. Therefore, a distance between an end portion 211c1 of the lower electrode 211 and an end portion 211a1 of the adjacent lower electrode 211 can be set to Md1. The distance between the end portion 10c of the semiconductor portion 10 and the adjacent end portion 10a is about a blade width Wb. Therefore, an end portion of the lower electrode 211 can coincide with or can be disposed inside an end portion of the semiconductor portion 10. The distance between an end portion 211c2 of the lower electrode 211 at a position narrowed in a direction from the first face 1001a toward the second face 1001b of the semiconductor substrate 1001 and an end portion 211a2 of the adjacent lower electrode 211 can be further increased to be larger than the distance between the end portion 211c1 and the end portion 211a1.

FIG. 29 is a schematic perspective cross-sectional view illustrating a part F in FIG. 26 in an enlarged manner.

As shown in FIG. 29, a distance between an end portion 1002c and an end portion 1002a of the adjacent semiconductor layers 1002 can be set to a width Md1 of the mask shown in FIG. 24 set based on the dicing width Wd. Therefore, in the example in FIG. 29, a position of the end portion 211c1 of the lower electrode 211 can coincide with the end portion 1002c of the semiconductor layer 1002 or can be disposed inside the end portion 1002c.

Since wet etching is used to form the lower electrode 211, a side surface of the lower electrode 211 can be tapered by further etching from the first face 1001a toward the second face 1001b of the semiconductor substrate 1001. A degree of tapering can be set more appropriately according to conditions of the wet etching or the like. In the example in FIG. 29, since the end portion 211c2 of the lower electrode 211 is located outside the end portion R1a of the first element region R1, a sufficient thickness of the lower electrode 211 can be secured in the first element region R1.

In the variation, the distance between the adjacent seed metals 2020a can be set to the mask width Md1. The mask width Md1 can be set based on the dicing width Wd. A sufficient distance can be secured such that the semiconductor layer 1002 is not cut by the dicing blade 1100. For example, when the mask width Md1 is equal to the dicing width Wd, the resist mask 2010 is easily formed.

In this manner, it is possible to obtain a semiconductor device capable of preventing warpage and a method of manufacturing the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a conductive layer;
a semiconductor portion provided on the conductive layer;
a first source electrode provided on the semiconductor portion;
a second source electrode provided on the semiconductor portion and provided away from the first source electrode;
a first control electrode that is provided on the semiconductor portion and that is electrically isolated from the first source electrode and the second source electrode; and
a second control electrode that is provided on the semiconductor portion and that is electrically isolated from the first source electrode, the second source electrode, and the first control electrode,
the semiconductor portion including
a first semiconductor region of a first conductivity type provided on the conductive layer,
a second semiconductor region of a second conductivity type provided on the first semiconductor region,
a third semiconductor region of the second conductivity type provided on the first semiconductor region and provided away from the second semiconductor region,
a fourth semiconductor region of the first conductivity type provided on the second semiconductor region, and
a fifth semiconductor region of the first conductivity type provided on the third semiconductor region,
the first source electrode being electrically connected to the second semiconductor region and the fourth semiconductor region,
the second source electrode being electrically connected to the third semiconductor region and the fifth semiconductor region,
the first control electrode facing the first semiconductor region, the second semiconductor region, and the fourth semiconductor region via a first insulating film,
the second control electrode facing the first semiconductor region, the third semiconductor region, and the fifth semiconductor region via a second insulating film, and
in a plan view,
a first end portion of the conductive layer being located inside a second end portion of the semiconductor portion, and
an outer periphery formed by the first end portion surrounding both at least a part of a third end portion of a first element region including the second semiconductor region and at least a part of a fourth end portion of a second element region including the third semiconductor region.

2. The device according to claim 1, wherein
the first end portion is located outside the third end portion and outside the fourth end portion in a plan view.

3. The device according to claim 1, wherein
the third end portion coincides with an end portion of the second semiconductor region and the fourth end portion coincides with an end portion of the third semiconductor region in a plan view.

4. The device according to claim 1, wherein
the conductive layer is a frustum having an upper surface facing the semiconductor portion and a lower surface located on a side opposite to the upper surface, and
the frustum becomes thinner from the upper surface toward the lower surface.

5. A method of manufacturing a semiconductor device, the method comprising:
preparing a semiconductor substrate having a first face and a second face located on a side opposite to the first face and having a plurality of semiconductor layers formed on the first face;
forming a mask layer on the second face between two adjacent semiconductor layers among the plurality of semiconductor layers according to a first distance between the two semiconductor layers;
forming a conductive layer on the second face and the mask layer;
forming two first conductive portions (seed metals) corresponding to positions of the two semiconductor layers by removing the mask layer;
forming two second conductive portions on the two first conductive portions; and
dicing the semiconductor substrate between the two semiconductor layers,
the first distance being set based on setting of a dicing blade configured to dice the semiconductor substrate,
a width of the mask layer being set based on the first distance, and
each of the plurality of semiconductor layers including
a first semiconductor region of a first conductivity type provided on the semiconductor substrate,
a second semiconductor region of a second conductivity type provided on the first semiconductor region,
a third semiconductor region of the second conductivity type provided on the first semiconductor region and provided away from the second semiconductor region,
a fourth semiconductor region of the first conductivity type provided on the second semiconductor region, and
a fifth semiconductor region of the first conductivity type provided on the third semiconductor region.

6. The method according to claim 5, wherein
the width of the mask layer is set based on positions of an end portion of a first element region including the second semiconductor region and an end portion of a second element region including the third semiconductor region.

7. The method according to claim 6, wherein
each of the plurality of semiconductor layers includes
a first control electrode facing the first semiconductor region, the second semiconductor region, and the fourth semiconductor region via a first insulating film, and
a second control electrode facing the first semiconductor region, the third semiconductor region, and the fifth semiconductor region via a second insulating film,
the second semiconductor region and the fourth semiconductor region are electrically connected, and
the third semiconductor region and the fifth semiconductor region are electrically connected.

8. A method of manufacturing a semiconductor device, the method comprising:
preparing a semiconductor substrate that has a first face and a second face located on a side opposite to the first face and that has a plurality of semiconductor layers formed on the first face;
forming a third conductive layer on the second face;
forming a second mask layer on the third conductive layer between two adjacent semiconductor layers among the plurality of semiconductor layers according to a first distance between the two semiconductor layers;
forming two third conductive layers corresponding to positions of the two semiconductor layers by dividing the third conductive layer by etching; and
removing the mask layer and dicing the semiconductor substrate between the two semiconductor layers,
the first distance being set based on setting of a dicing blade configured to dice the semiconductor substrate,
a width of the second mask layer being set based on the first distance, and
each of the plurality of semiconductor layers including
a first semiconductor region of a first conductivity type provided on the semiconductor substrate,
a second semiconductor region of a second conductivity type provided on the first semiconductor region,
a third semiconductor region of the second conductivity type provided on the first semiconductor region and provided away from the second semiconductor region,
a fourth semiconductor region of the first conductivity type provided on the second semiconductor region, and
a fifth semiconductor region of the first conductivity type provided on the third semiconductor region.

9. The method according to claim 8, wherein
the forming the two third conductive layers includes wet etching.

10. The method according to claim 8, wherein
each of the plurality of semiconductor layers includes
a first control electrode facing the first semiconductor region, the second semiconductor region, and the fourth semiconductor region via a first insulating film, and
a second control electrode facing the first semiconductor region, the third semiconductor region, and the fifth semiconductor region via a second insulating film,
the second semiconductor region and the fourth semiconductor region are electrically connected, and
the third semiconductor region and the fifth semiconductor region are electrically connected.
